(19) United States
(12) Patent Application Publication
(10) Pub. No.: US 2026/0175737 A1
(43) Pub. Date: Jun. 25, 2026

(54) BATTERY MANAGEMENT DEVICE

(71) Applicant: TOYOTA JIDOSHA KABUSHIKI KAISHA, Toyota-shi (JP)

(72) Inventors: Daiki TERASHIMA, Okazaki-shi (JP); Hiroki NAGAI, Aichi-ken (JP)

(73) Assignee: TOYOTA JIDOSHA KABUSHIKI KAISHA, Toyota-shi (JP)

(21) Appl. No.: 19/300,876

(22) Filed: Aug. 15, 2025

(30) Foreign Application Priority Data
Dec. 23, 2024 (JP) 2024-226565

(51) Int. Cl. B60L 58/10; G01R 31/389; H01M 10/42

(52) U.S. Cl. CPC B60L 58/10; G01R 31/389; H01M 10/425; H01M 2010/4271

(57) ABSTRACT

A battery management device according to the present disclosure comprises one or more of processors that restrict an output of a battery. The one or more processors are configured to relax the output restriction of the battery until completion of transport of the battery electric vehicle after shipment. The one or more processors are configured to determine that the transport of the battery electric vehicle after the shipment has been completed, in response to a charging history of the battery being recorded.

### CROSS-REFERENCE TO RELATED APPLICATION

This application claims priority to Japanese Patent Application No. 2024-226565

filed on Dec. 23, 2024. The disclosure of the above-identified application, including the specification, drawings, and claims, is incorporated by reference herein in its entirety.

### BACKGROUND

### 1. Technical Field

The present disclosure relates to a battery management device that manages a battery of a battery electric vehicle.

2. Description of Related Art

Japanese Unexamined Patent Application Publication No. 2019-094013 (JP 2019-094013 A) discloses a control device in a hybrid electric vehicle including an internal combustion engine (engine) and an electric motor (electric drive), the control device executing control to temporarily increase an output restriction of a battery under a predetermined condition in a case where the internal combustion engine is started, a case where an accelerator pedal is deeply depressed, or the like.

### SUMMARY

In recent years, a demand for a battery electric vehicle that travels on electric energy stored in a battery has increased, and the number of produced battery electric vehicles has increased. In the production of the battery electric vehicle, a production cost can be reduced by reducing a state of charge (SOC) of the battery at the time of shipment from a production factory. This is because costs associated with charging the battery in a production process can be reduced.

On the other hand, a vehicle including the battery electric vehicle is transported by a suitable transport vehicle (for example, a carrier car or a ship) after being shipped from the production factory and is delivered to a distributor. In the shipment and transport of the vehicle, the vehicle needs to be temporarily started and travel, such as for moving in a motor pool or loading onto a transport means. For this reason, particularly in a battery electric vehicle, the energy required until the transport is completed must be supplied from the SOC of the battery at the time of shipment. Furthermore, in the battery electric vehicle, maintaining the SOC at which traveling during the transport can be smoothly performed is required.

An object of the present disclosure is to provide a technique capable of reducing the SOC of a battery at the time of shipment of a battery electric vehicle.

According to one aspect of the present disclosure, there is provided a battery management device configured to manage an operation of a battery of a battery electric vehicle. The battery management device includes one or more processors that perform output restriction of the battery. The one or more processors are configured to relax the output restriction of the battery until completion of transport of the battery electric vehicle after shipment.

According to the present disclosure, the output restriction of the battery is relaxed until completion of transport of the battery electric vehicle after shipment. Accordingly, it is possible to reduce the SOC of the battery electric vehicle at the time of shipment. As a result, it is possible to reduce the production cost of the battery electric vehicle.

### BRIEF DESCRIPTION OF THE DRAWINGS

Features, advantages, and technical and industrial significance of exemplary embodiments of the disclosure will be described below with reference to the accompanying drawings, in which like signs denote like elements, and wherein:

FIG. 1 is a conceptual diagram for describing an outline of technical features of a battery management device according to the present embodiment;

FIG. 2 is a diagram showing an example of a map for determining an output restriction value related to an output restriction of a battery;

FIG. 3 is a diagram showing an example of a configuration of a battery electric vehicle to which the battery management device according to the present embodiment is applied;

FIG. 4 is a diagram showing an example of a functional configuration of the battery management device according to the present embodiment;

FIG. 5 is a flowchart showing a processing flow of processing executed by a restriction relaxation determination unit of the battery management device according to the present embodiment; and

FIG. 6 is a flowchart showing a processing flow of processing executed by a restriction relaxation determination unit according to Modification.

### DETAILED DESCRIPTION OF EMBODIMENTS

Hereinafter, embodiments of the present disclosure will be described with reference to drawings. In each of the figures, the same reference numeral is assigned to the same or corresponding part and a description thereof is simplified or omitted.

### 1. Outline

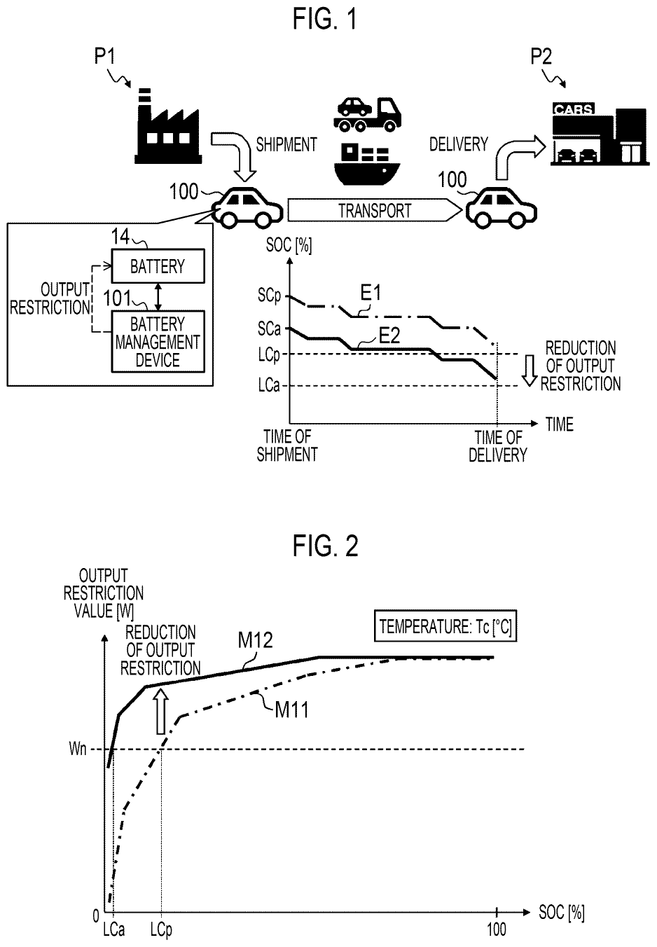

FIG. 1 is a conceptual diagram for describing an outline of technical features of a battery management device 101 according to the present embodiment. The battery management device 101 according to the present embodiment manages an operation of a battery 14 provided in a battery electric vehicle 100. The technical features of the battery management device 101 according to the present embodiment relates to management of the battery 14 until the battery electric vehicle 100 shipped from a production factory P1 is transported and delivered to a distributor P2. In the present embodiment, the battery electric vehicle 100 is a so-called battery electric vehicle (BEV) that travels on electric energy stored in the battery 14.

In the production of the battery electric vehicle 100, a production cost can be reduced by reducing an SOC at the time of shipment from the production factory P1. This is because costs (for example, a required time, equipment, and a place) associated with charging the battery 14 in a production process can be reduced. The same applies to a case where only the attachment of the battery 14 is performed at the production factory P1. This is because the costs associated with charging can be reduced in a factory that produces the battery 14.

On the other hand, the battery electric vehicle 100 is transported by suitable transport means after being shipped from the production factory P1. During this period, the battery electric vehicle 100 needs to be temporarily started and travel, such as moving in a motor pool or boarding the transport means. For this reason, in the battery electric vehicle 100, an SOC at the time of shipment needs to be compensated for energy required until the transport is completed. Furthermore, in the battery electric vehicle 100, it is necessary to maintain an SOC at which the battery electric vehicle 100 can travel with a sufficient driving force for smooth transport until the transport is completed. In general, in the management of the battery 14 of the battery electric vehicle 100, the output restriction according to the SOC and a temperature of the battery 14 is performed for the purpose of component protection or deterioration suppression. In a case where the SOC is excessively decreased due to the output restriction, an output of the battery 14 is insufficient, and traveling of the battery electric vehicle 100 is slowed. Alternatively, the battery electric vehicle 100 cannot travel. As a result, smooth transport is hindered.

The SOC at the time of shipment is set in consideration of the above circumstances. A graph in FIG. 1 shows an example of a change pattern of the SOC during a period from the shipment of the battery electric vehicle 100 to the completion of the transport. A pattern E1 and a pattern E2 have different SOCs at the time of shipment. Specifically, the SOC at the time of shipment in the pattern E1 is SCp, and the SOC at the time of shipment in the pattern E2 is SCa lower than SCp. In the graph in FIG. 1, LCp indicates a lower limit of the SOC (hereinafter, referred to as a “required charging rate”) at which the battery electric vehicle 100 can travel with a sufficient driving force. That is, it is necessary to maintain the SOC at LCp or more until the transport is completed. Here, it can be seen that the SOC cannot be maintained at LCp or more in the pattern E2 in which the SOC at the time of shipment is set to SCa. On the other hand, it can be seen that the SOC can be maintained at LCp or more in the pattern E1 in which the SOC at the time of shipment is set to SCp. Therefore, in a case where the required charging rate is LCp in the pattern shown in the graph in FIG. 1, the SOC at the time of shipment is set to, for example, SCp.

The required charging rate is obtained from a map or a look-up table in which the battery management device 101 determines an output restriction value related to the output restriction. The map or the look-up table is typically configured to provide the output restriction value according to the SOC and the temperature of the battery 14. Such a map or look-up table is experimentally created in advance through tests or the like in consideration of component protection or deterioration suppression while a user uses the battery electric vehicle 100.

FIG. 2 shows an example of a map for determining the output restriction value. However, for the sake of simplicity of description, FIG. 2 shows a map at a certain temperature Tc. FIG. 2 shows two maps, that is, a first map M11 and a second map M12. In FIG. 2, Wn is a lower limit value of the output of the battery 14 at which the battery electric vehicle 100 can travel with a sufficient driving force for smooth transport. That is, the required charging rate is an SOC at which the output restriction value is Wn. That is, as shown in FIG. 2, LCp is the required charging rate with respect to the first map M11.

The inventors of the present disclosure have focused on the output restriction in order to reduce the SOC at the time of shipment. The output restriction for the purpose of component protection or deterioration suppression is usually set in consideration of various use situations by the user, and is considered until the battery electric vehicle 100 continuously travels for a long time. On the other hand, the traveling of the battery electric vehicle 100 until the transport is completed is for a short period. For this reason, even in a case where the battery electric vehicle 100 travels on a driving force that is to some extent higher than the default output restriction until the transport is completed, the purpose of component protection or deterioration suppression is not impaired. Therefore, the battery management device 101 according to the present embodiment is configured to relax the output restriction until completion of transport of the battery electric vehicle 100 after shipment.

For example, the battery management device 101 is configured to switch the map for determining the output restriction value from the first map M11 to the second map M12 until completion of transport of the battery electric vehicle 100 after shipment. As shown in FIG. 2, in the second map M12, the output restriction is relaxed as compared with the first map M11, and the output restriction value is Wn or more even in a case where the SOC is LCp. That is, the required charging rate can be decreased. Specifically, the required charging rate is LCa from LCp. As a result, as shown in FIG. 1, it can be seen that, even in the pattern E2, the SOC during the period until the transport is completed can be maintained at LCa or more, which is the required charging rate. That is, the SOC at the time of shipment can be reduced from SCp to SCa. Alternatively, the battery management device 101 may be configured to relax the output restriction by dynamically correcting the map for determining the output restriction value. In this manner, with the battery management device 101 according to the present embodiment, it is possible to reduce the SOC of the battery electric vehicle 100 at the time of shipment.

### 2. Configuration of Battery Electric Vehicle

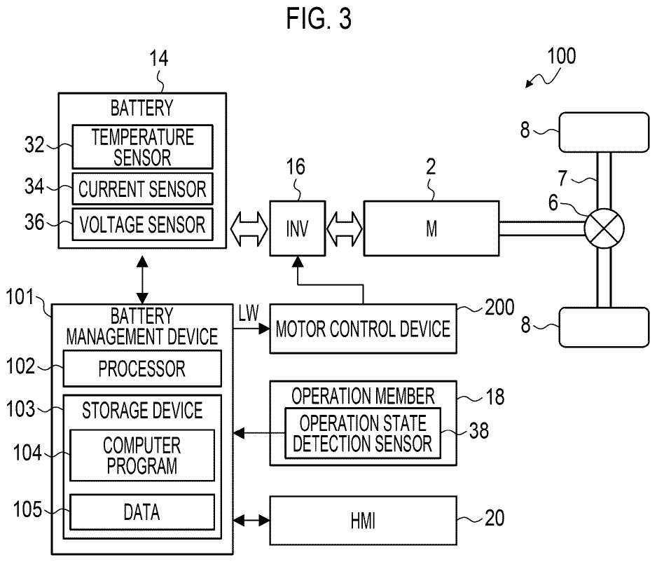

Hereinafter, a configuration of the battery electric vehicle 100 to which the battery management device 101 according to the present embodiment is applied will be described. FIG. 3 is a diagram showing an example of the configuration of the battery electric vehicle 100.

The battery electric vehicle 100 comprises an electric motor (M) 2 as a driving source for traveling. The electric motor 2 is, for example, a three-phase alternating current motor. An inverter (INV) 16 is attached to the electric motor 2. An output shaft of the electric motor 2 is connected to a propeller shaft 5 via a reducer (not shown). The propeller shaft 5 is connected to a differential gear 6. The differential gear 6 is connected to left and right driving wheels 8 by left and right drive shafts 7. The driving wheel 8 may be a front wheel or a rear wheel. The inverter 16, the electric motor 2, the reducer, and the differential gear 6 may be integrally configured as an e-axis. In this case, the e-axis is directly connected to the drive shaft 7 without the propeller shaft 5.

The inverter 16 is connected to the battery 14. The inverter 16 is, for example, a voltage type inverter and controls a motor torque of the electric motor 2 through PWM control. The battery 14 is typically a high-voltage battery composed of a plurality of battery cells. For example, a lithium ion battery, a nickel hydrogen battery, or an all-solid state battery is employed as each of the battery cells. The battery 14 is provided with a temperature sensor 32, a current sensor 34, and a voltage sensor 36. The temperature sensor 32 outputs a signal indicating a temperature of the battery 14. The current sensor 34 outputs a signal indicating a current value of a current flowing through each of the portions of the battery 14. The voltage sensor 36 outputs a signal indicating a voltage value between terminals of the battery 14 or each of the battery cells.

The battery electric vehicle 100 comprises various operation members 18. Examples of the operation member 18 include a wiper switch, a turn signal switch, a door switch, a multimedia control switch, a horn switch, a starter switch, a room lamp switch, a side brake operation device, a steering wheel, an accelerator pedal, a brake pedal, and a shifter. An operation state detection sensor 38 is provided in each of the operation members 18. The operation state detection sensor 38 outputs a signal indicating an operation state of each of the operation members 18. For example, the operation state detection sensor 38 provided in each of the switches outputs a signal indicating a pressed state of each switch. Furthermore, for example, the operation state detection sensor 38 provided in the steering wheel outputs a signal indicating a steering angle of the steering wheel. Furthermore, for example, the operation state detection sensor 38 provided in the accelerator pedal outputs a signal indicating an accelerator operation amount.

In addition, the battery electric vehicle 100 comprises a human machine interface (HMI) 20. The HMI 20 presents various types of information to the driver by display or sound, and also receives various types of inputs from the driver. The HMI 20 includes a display (for example, a multi-information display, a meter display, or a multimedia display), an indicator lamp, a touch screen, a switch, a touch pad, a speaker phone, a microphone, and the like. The operation member 18 may function as a part of the HMI 20 for receiving various inputs.

The battery electric vehicle 100 comprises the battery management device 101 and a motor control device 200. The battery management device 101 is connected to the battery 14 and manages the operation of the battery 14. The motor control device 200 is connected to the inverter 16 and controls an output of the electric motor 2 through the PWM control by the inverter 16. The battery management device 101 and the motor control device 200 are typically electronic control units (ECUs). Each of the battery management device 101 and the motor control device 200 may be a combination of a plurality of ECUs.

The battery management device 101 is configured to acquire signals from the temperature sensor 32, the current sensor 34, and the voltage sensor 36 provided in the battery 14. In addition, the battery management device 101 is configured to acquire signals from the operation state detection sensor 38 and the HMI 20 via an in-vehicle network such as a control area network (CAN). The battery management device 101 generates a control signal for managing the operation of the battery 14 based on the acquired signals. In particular, the battery management device 101 restricts the output of the battery 14 as the management of the battery 14. That is, the control signal generated by the battery management device 101 includes an output restriction value LW related to the output restriction of the battery 14. The battery management device 101 transmits the output restriction value LW to the motor control device 200.

The battery management device 101 comprises one or a plurality of processors 102 (hereinafter, simply referred to as a processor 102) and one or a plurality of storage devices 103 (hereinafter, simply referred to as a storage device 103).

The processor 102 executes various types of processing. The processor 102 is configured by, for example, a general-purpose processor, a specific-purpose processor, a central processing unit (CPU), a graphics processing unit (GPU), an application specific integrated circuit (ASIC), a field-programmable gate array (FPGA), an integrated circuit, a circuit of the related art, and a combination of one or a plurality thereof. The processor 102 can also be referred to as processing circuitry. The processing circuitry is hardware programmed to realize a function of the battery management device 101 or hardware that executes the function of the battery management device 101.

The storage device 103 stores various types of information necessary for executing processing of the processor 102. The storage device 103 is configured by, for example, a recording medium such as a random access memory (RAM), a read only memory (ROM), a solid state drive (SSD), or a hard disk drive (HDD). The storage device 103 stores a computer program 104 that can be executed by the processor 102 and various types of data 105. The computer program 104 is composed of a plurality of instruction codes describing processing executed by the processor 102. The computer program 104 is recorded in a computer-readable recording medium. A function of the battery management device 101 is realized by cooperation between the processor 102 that executes the computer program 104 and the storage device 103.

The motor control device 200 calculates a target driving force of the battery electric vehicle 100 according to a driving operation of the driver based on a signal from a sensor system including a sensor (for example, a vehicle speed sensor or a motor rotation speed sensor) (not shown). Examples of the signal input from the sensor system to the motor control device 200 include a signal indicating a vehicle speed of the battery electric vehicle 100, a signal indicating an operation state of the accelerator pedal, a signal indicating an operation state of the brake pedal, a signal indicating a rotation speed of the electric motor 2, and a signal indicating various states of the battery 14. The motor control device 200 calculates the target driving force using, for example, a map. In this case, the map is configured to provide the target driving force according to an operation state of a driving operation member (for example, an accelerator operation amount or a brake operation amount) and a traveling state of the battery electric vehicle 100 (for example, a rotation speed of the electric motor 2 or a vehicle speed). The motor control device 200 controls the output of the electric motor 2 to realize the calculated target driving force.

In the present embodiment, the motor control device 200 is further configured to control the output of the electric motor 2 in consideration of the output restriction value LW acquired from the battery management device 101. That is, the motor control device 200 calculates the target driving force such that the output of the battery 14 does not exceed the output restriction value LW. For example, the motor control device 200 saturates the target driving force in a case where the output restriction value LW is reached. In addition, for example, the motor control device 200 corrects a map that provides the target driving force according to the output restriction value LW. In this manner, the output restriction of the battery 14 by the battery management device 101 can be realized. As a functional configuration of the motor control device 200, a known suitable method used to calculate a target driving force in a normal BEV according to the related art can be employed.

As described above, the battery electric vehicle 100 to which the battery management device 101 according to the present embodiment is applied is configured. The battery management device 101 can also be referred to as a battery management system (BMS) together with the sensor system.

### 3. Functional Configuration of Battery Management Device

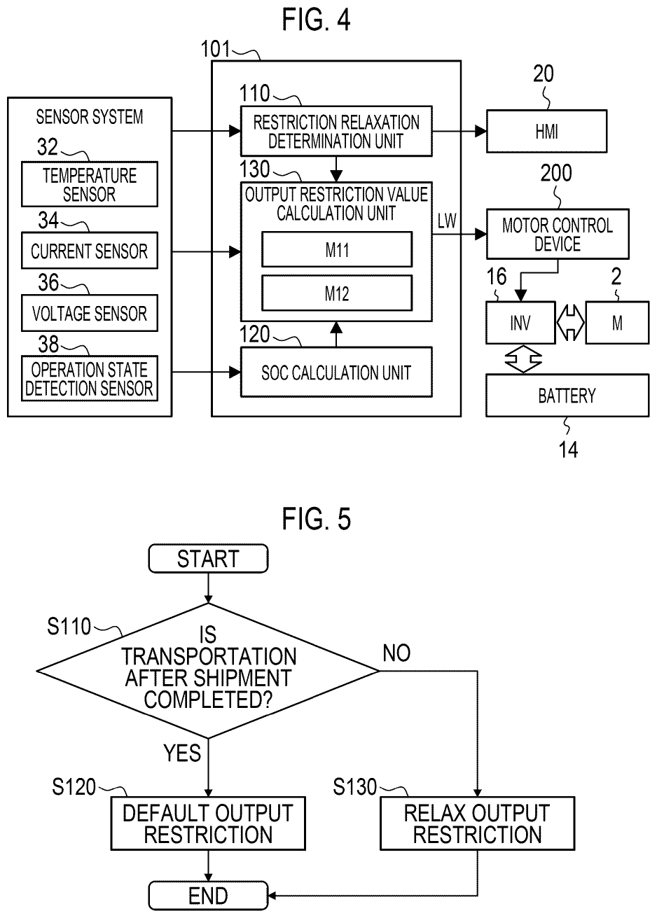

Hereinafter, a functional configuration of the battery management device 101 according to the present embodiment will be described. FIG. 4 is a diagram showing an example of the functional configuration of the battery management device 101. A signal from the sensor system is input to the battery management device 101. The signal input from the sensor system to the battery management device 101 includes a signal indicating the temperature of the battery 14, a signal indicating a current value of a current flowing through each of the portions of the battery 14, a signal indicating a voltage value between terminals of the battery 14 or each battery cell, and a signal indicating an operation state of various operation members 18 of the battery electric vehicle 100.

The battery management device 101 includes a restriction relaxation determination unit 110, an SOC calculation unit 120, and an output restriction value calculation unit 130 as functional blocks. These functional blocks are realized by cooperation between the processor 102 that executes the computer program 104 and the storage device 103.

The restriction relaxation determination unit 110 determines whether or not to relax the output restriction. The restriction relaxation determination unit 110 determines to relax the output restriction until completion of transport of the battery electric vehicle 100 after shipment. In addition, the restriction relaxation determination unit 110 determines to perform the default output restriction after the transport of the battery electric vehicle 100 is completed. The restriction relaxation determination unit 110 transmits the determination result to the output restriction value calculation unit 130. Furthermore, the battery management device 101 may be configured to transmit the determination result of the restriction relaxation determination unit 110 to the HMI 20. In this case, the HMI 20 may be configured to notify the user that the output restriction is being relaxed by display or sound while the determination result indicating the relaxation of the output restriction is acquired. The restriction relaxation determination unit 110 can determine whether or not the transport of the battery electric vehicle 100 after the shipment is completed from the following aspects.

A first aspect relates to a charging history of the battery 14. Of course, the charging history of the battery 14 is in an initial state immediately after the battery electric vehicle 100 is shipped from the production factory P1. It is assumed that the battery electric vehicle 100 is charged by the distributor P2 after being delivered to the distributor P2. In particular, it is not assumed that the battery electric vehicle 100 is charged during the transport. Therefore, according to this aspect, the restriction relaxation determination unit 110 determines that the transport of the battery electric vehicle 100 after the shipment is completed in response to the recording of the charging history of the battery 14. Alternatively, the restriction relaxation determination unit 110 may determine that the transport of the battery electric vehicle 100 after the shipment is not completed while the charging history of the battery 14 is in the initial state (for example, no record).

A second aspect relates to a specific operation on the operation member 18. Of course, in the production factory P1, the transport of the battery electric vehicle 100 after the shipment is not completed. In addition, a worker in the production factory P1 can operate each of the operation members 18 of the battery electric vehicle 100 produced before the shipment. Therefore, according to this aspect, the restriction relaxation determination unit 110 determines that the transport of the battery electric vehicle 100 after the shipment is not completed in response to the specific operation on the operation member 18. The restriction relaxation determination unit 110 can determine whether or not the specific operation has been performed on the operation member 18 based on a signal from the operation state detection sensor 38. It is desirable that the specific operation is not performed at all in normal use of the battery electric vehicle 100. This is to prevent the user of the battery electric vehicle 100 from accidentally performing the specific operation. For example, the specific operation is an operation of turning on and off left and right turn signals twice alternately and then blowing a horn within a predetermined time (for example, 10 seconds). By the way, in the distributor P2, of course, the transport of the battery electric vehicle 100 after the shipment is completed. Therefore, the restriction relaxation determination unit 110 may determine that the transport of the battery electric vehicle 100 after the shipment is completed in response to the specific operation on the operation member 18.

FIG. 5 is a flowchart showing a processing flow of processing executed by the restriction relaxation determination unit 110. The processing flow shown in FIG. 5 is repeatedly executed in a predetermined processing cycle.

In S110, the restriction relaxation determination unit 110 determines whether or not the transport of the battery electric vehicle 100 after the shipment is completed. In a case where it is determined that the transport after the shipment is completed (S110; Yes), the restriction relaxation determination unit 110 determines to perform the default output restriction (S120), and ends the processing. In a case where it is determined that the transport after the shipment is not completed (S110; No), the restriction relaxation determination unit 110 determines to relax the output restriction (S130), and ends the processing.

Referring to FIG. 4 again. The SOC calculation unit 120 calculates the SOC of the battery 14 based on signals from the current sensor 34 and the voltage sensor 36. As a method of calculating the SOC in the SOC calculation unit 120, a known suitable technique may be employed. The SOC calculation unit 120 transmits the calculated SOC to the output restriction value calculation unit 130.

The output restriction value calculation unit 130 calculates the output restriction value LW for the SOC and the temperature of the battery 14 using the map. In particular, in a case where a determination result indicating the default output restriction is acquired, the output restriction value calculation unit 130 uses the first map M11. On the other hand, in a case where a determination result indicating the relaxation of the output restriction is acquired, the output restriction value calculation unit 130 uses the second map M12. That is, the first map M11 is a map for calculating the default output restriction value LW, and the second map M12 is a map for calculating the relaxed output restriction value LW (see FIG. 2). The first map M11 and the second map M12 may be experimentally created in advance through tests or the like, and be stored in the storage device 103 as the computer program 104 or the data 105. The battery management device 101 transmits the output restriction value LW calculated by the output restriction value calculation unit 130 to the motor control device 200.

The output restriction value calculation unit 130 may be configured to correct the first map M11 and calculate the output restriction value LW using the corrected first map M11 in a case where the determination result indicating the relaxation of the output restriction is acquired. In this case, the output restriction value calculation unit 130 may be configured to estimate an internal resistance of the battery 14 based on signals from the current sensor 34 and the voltage sensor 36, and calculate a correction value of the first map M11 according to the estimated internal resistance. The internal resistance of the battery 14 is an indicator of a deterioration state of the battery 14. Therefore, in a case where the internal resistance is equal to or greater than a predetermined value, the output restriction value calculation unit 130 may set the correction value to be smaller.

### 4. Modification: Determination of Relaxation of Output Restriction According to State of Battery

The battery management device 101 according to the present embodiment may employ an aspect modified as follows.

In recent years, a demand for reuse and recycling of the battery 14 has increased. Therefore, even the battery 14 provided in the battery electric vehicle 100 immediately after the production is assumed to be in a deteriorated state to some extent. In a case where the deterioration of the battery 14 has progressed to certain extent, the battery 14 may be significantly deteriorated even in a case where the output restriction is relaxed for a short period. In order to address this issue, the restriction relaxation determination unit 110 of the battery management device 101 may be further configured to determine whether or not a state of the battery 14 is a state in which the relaxation of the output restriction is not allowable (hereinafter, referred to as a “relaxation-prohibited state”). In addition, the restriction relaxation determination unit 110 may be configured to determine to perform the default output restriction (not to relax the output restriction) in a case where the battery 14 is in the relaxation-prohibited state.

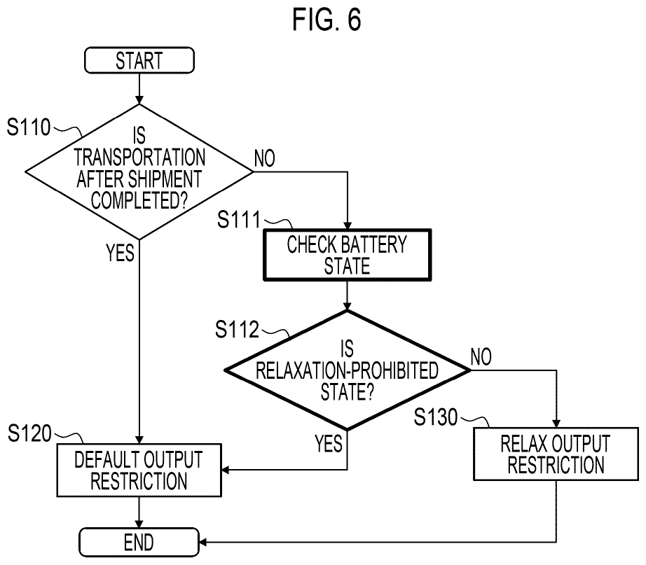

FIG. 6 is a flowchart showing a processing flow of processing executed by the restriction relaxation determination unit 110 according to Modification. The processing flow shown in FIG. 6 is repeatedly executed in a predetermined processing cycle. In the processing flow shown in FIG. 6, processing related to S111 and S112 is added as compared with the processing flow shown in FIG. 5.

In Modification, in a case where it is determined that the transport after the shipment is not completed (S110; No), the processing proceeds to S111. In S111, the restriction relaxation determination unit 110 checks the state of the battery 14. For example, the restriction relaxation determination unit 110 estimates an internal resistance of the battery 14 based on signals from the current sensor 34 and the voltage sensor 36. In addition, in a case where the estimated internal resistance exceeds a threshold value, the restriction relaxation determination unit 110 determines that the state of the battery 14 is the relaxation-prohibited state. Further, for example, the restriction relaxation determination unit 110 calculates a cumulative discharge amount based on a discharge history of the battery 14. In addition, in a case where the calculated cumulative discharge amount exceeds a threshold value, the restriction relaxation determination unit 110 determines that the state of the battery 14 is the relaxation-prohibited state.

In a case where it is determined as a result of the processing related to S111 that the state of the battery 14 is the relaxation-prohibited state (S120; Yes), the restriction relaxation determination unit 110 determines to perform the default output restriction (S120), and ends the processing. On the other hand, in a case where it is determined that the state of the battery 14 is not the relaxation-prohibited state (S120; No), the restriction relaxation determination unit 110 determines to relax the output restriction (S130), and ends the processing.

What is claimed is:

1. A battery management device configured to manage an operation of a battery of a battery electric vehicle, the battery management device comprising one or more processors that perform output restriction of the battery, wherein the one or more processors are configured to relax the output restriction of the battery until completion of transport of the battery electric vehicle after shipment.

2. The battery management device according to claim 1, wherein the one or more processors are configured to determine that the transport of the battery electric vehicle after the shipment has been completed, in response to a charging history of the battery being recorded.

3. The battery management device according to claim 1, wherein the one or more processors are configured to determine that the transport of the battery electric vehicle after the shipment has not been completed, in response to a specific operation being performed on an operation member provided in the battery electric vehicle.

4. The battery management device according to claim 1, wherein the one or more processors are further configured to inhibit relaxation of the output restriction in a case where a state of the battery is a relaxation-prohibited state in which the relaxation of the output restriction is not permitted.

5. The battery management device according to claim 4, wherein the one or more processors are configured to
estimate an internal resistance of the battery, and
determine that the battery is in the relaxation-prohibited state in a case where the internal resistance exceeds a threshold value.
